(19) United States
(12) Patent Application Publication
(10) Pub. No.: US 2026/0217038 A1
(43) Pub. Date: Jul. 30, 2026

(54) DROPLET PLACEMENT DEVICE, DROPLET PLACEMENT METHOD, AND DISPLAY DEVICE MANUFACTURING METHOD

(71) Applicant: CANON KABUSHIKI KAISHA, Tokyo (JP)

(72) Inventors: SHINICHI WATANABE, Tochigi (JP); MASAHIRO ITO, Tochigi (JP); KYOHEI SHIBUYA, Saitama (JP)

(21) Appl. No.: 19/458,332

(22) Filed: Jan. 23, 2026

(30) Foreign Application Priority Data
Jan. 30, 2025 (JP) 2025-014098

(51) Int. Cl. B41J 11/00; B41J 2/045; B41J 3/28; B41J 3/407; B41J 11/06; B41J 11/14; B41J 13/00; G06K 15/00; G06K 15/02; H10K 59/12; H10K 71/13

(52) U.S. Cl. CPC B41J 11/008; B41J 2/04573; B41J 2/04586; B41J 3/28; B41J 3/407; B41J 11/0095; B41J 11/06; B41J 11/14; B41J 13/0027; G06K 15/1809; G06K 15/1848; G06K 15/408; H10K 59/1201; H10K 71/135

(57) ABSTRACT

Some embodiments of a droplet placement device include a substrate holder configured to hold a plurality of substrates spaced apart from each other, a discharge head configured to discharge a droplet, a scanning mechanism configured to relatively move the substrate holder with respect to the discharge head to continuously scan a region including the plurality of substrates with respect to the discharge head, an alignment measurement device configured to measure alignment errors of the plurality of substrates held by the substrate holder, and a controller configured to control the discharge head and the scanning mechanism based on the alignment errors measured using the alignment measurement device to provide droplets to a plurality of target locations of the respective substrates in a period in which the region is continuously scanned by the scanning mechanism.

### BACKGROUND

### Field of the Technology

The present disclosure relates to a droplet placement device, a droplet placement method, and a display device manufacturing method.

### Description of the Related Art

Forming a pattern on a substrate using a droplet placement device that supplies a liquid material for a functional element as droplets onto the substrate by an inkjet method has been attempted. Patterning using such a droplet placement device offers advantages such as high use efficiency of a material because on-demand patterning is possible, a relatively compact manufacturing apparatus because of a non-vacuum process, and quick application to a large area. The droplet placement device can be used to, for example, manufacture a display device such as a flat panel display. The display device can be, for example, a display device using an organic Electro Luminescence (EL) element (OLED). An organic EL material for forming an organic EL element is expensive, so it is advantageous to use a droplet placement device capable of applying a material quickly to a large area at high material use efficiency. In the manufacturing process of an organic EL element, a light-emitting element portion may be manufactured after forming a Thin Film Transistor (TFT) element and then dividing one substrate into pieces. It is desired to process even such a divided substrate with high productivity.

Japanese U.S. Pat. No. 4,876,993 has disclosed a method of applying functional droplets to two works. According to this method, processing of applying functional droplets by an even number of scans is performed on one work, and then processing of applying functional droplets by an even number of scans starts for the other work.

The method described in Japanese U.S. Pat. No. 4,876,993 suffers low efficiency because processing on one work is performed and then processing on the other work starts.

### SUMMARY

Embodiments of the present disclosure provide techniques advantageous for increasing the efficiency of processing of placing droplets onto two substrates spaced apart from each other.

According to some embodiments, the present disclosure provides a droplet placement device comprising a substrate holder configured to hold a plurality of substrates spaced apart from each other; a discharge head configured to discharge a droplet; a scanning mechanism configured to relatively move the substrate holder with respect to the discharge head to continuously scan a region including the plurality of substrates with respect to the discharge head; an alignment measurement device configured to measure alignment errors of the plurality of substrates held by the substrate holder; and a controller configured to control the discharge head and the scanning mechanism based on the alignment errors measured using the alignment measurement device to provide droplets to a plurality of target locations of the respective substrates in a period in which the region is continuously scanned by the scanning mechanism.

Features of various embodiments will become apparent from the following description of embodiments with reference to the attached drawings. The following description of embodiments is described by way of example.

### BRIEF DESCRIPTION OF THE DRAWINGS

FIG. 1 is a view schematically showing the configuration of a manufacturing facility according to a first embodiment.

FIG. 2 is a view schematically showing the configuration of a droplet placement device according to the first embodiment.

FIG. 3 is a schematic view of the substrate stage of the droplet placement device when viewed from the top according to the first embodiment.

FIG. 4 is a functional block diagram of the stage controller of the droplet placement device according to the first embodiment.

FIG. 5 is a functional block diagram of a controller according to the first embodiment.

FIG. 6 is a flowchart showing the operation sequence of the droplet placement device according to the first embodiment.

FIG. 7 is a flowchart showing a measurement sequence according to the first embodiment.

FIG. 8 is a flowchart showing a discharge preparation sequence according to the first embodiment.

FIG. 9 is a view schematically showing the operation of the substrate stage in droplet placement processing by the droplet placement device according to the first embodiment.

FIG. 10 is a view schematically showing the operation of the substrate stage in the droplet placement processing by the droplet placement device according to the first embodiment.

FIGS. 11A to 11C are views exemplifying the operation of the substrate stage in the measurement sequence according to the first embodiment.

FIGS. 12A and 12B are views for explaining processing of reflecting an alignment calculation result in each pixel in the droplet placement device according to the first embodiment.

FIGS. 13A to 13C are views exemplifying the relationship between an alignment error in the X-axis direction (non-scanning direction) and a use nozzle in the droplet placement device according to the first embodiment.

FIG. 14 is a schematic view of the substrate stage of the droplet placement device when viewed from the top according to the first embodiment.

FIG. 15 is a view schematically showing the operation of the substrate stage in the droplet placement processing by the droplet placement device according to the first embodiment.

FIG. 16 is a functional block diagram of a controller according to the second embodiment.

FIG. 17 is a view schematically showing the operation of a substrate stage in droplet placement processing by a droplet placement device according to the second embodiment.

FIG. 18 is a view exemplifying shift components SX and SY of an alignment error.

FIG. 19 is a view exemplifying a shift component Sθ of the alignment error.

FIG. 20 is a view exemplifying a magnification component MX of the alignment error.

FIG. 21 is a view exemplifying a magnification component MY of the alignment error.

FIG. 22 is a view exemplifying a distortion component DR of the alignment error.

FIG. 23 is a view exemplifying a distortion component Yaw of the alignment error.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the following description, ordinal numbers attached to terms representing elements such as members or data, like the first substrate and the second substrate, are merely used to discriminate a plurality of elements from each other, and do not represent the order or the superiority or inferiority, unless otherwise explicitly specified.

In the manufacturing process of an organic EL display (OLED display), for example, a large substrate, such as a G6 substrate (1,850 mm×1,500 mm) or a G8 substrate (2,500 mm×2,200 mm), is available. A substrate can be properly selected from a glass substrate, a plastic substrate, and the like in accordance with a target article to be manufactured. A substrate is typically a plate-like member, but its form is not limited to a specific one as long as the member can function as a substrate, and the member may be, for example, a deformable film. In the manufacture of an organic EL display device, a G6 or G8 substrate may be divided and processed during the manufacturing process for the purpose of increasing the efficiency and yield of panel manufacturing and the like.

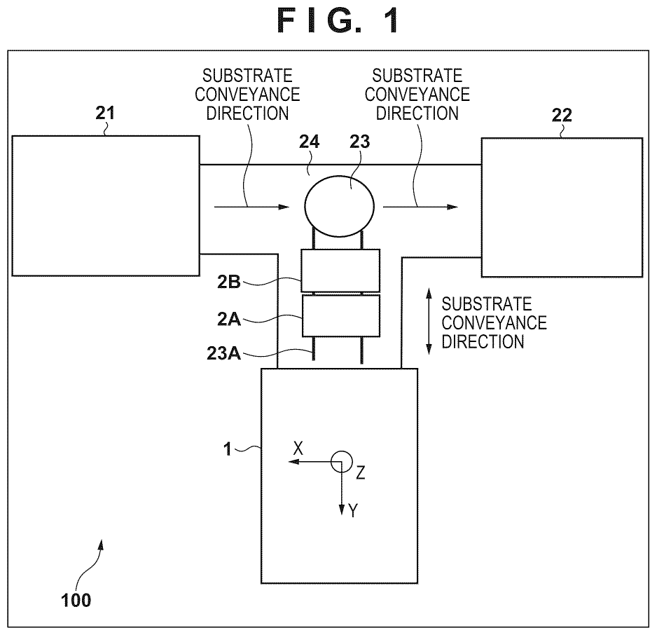

FIG. 1 schematically shows the configuration of a manufacturing facility 100 according to the first embodiment. The manufacturing facility 100 shown in FIG. 1 can be used to, for example, manufacture a display device, such as an organic EL display device. The manufacturing facility 100 can include, for example, a preprocessing device 21, a substrate conveyance robot 23, a substrate conveyance path 24, a droplet placement device 1, and a postprocessing device 22. A substrate 2A and a substrate 2B are intermediate products of a display device that is manufactured or processed by the manufacturing facility 100, and can be, for example, substrates obtained by dividing a G6 or G8 substrate into two. The substrates 2A and 2B can be conveyed via the substrate conveyance path 24 between the preprocessing device 21, the substrate conveyance robot 23, the droplet placement device 1, and the postprocessing device 22. When manufacturing an organic EL display, the preprocessing device 21 can be a vapor deposition device for forming an organic layer, the droplet placement device 1 can be a sealing device for forming a sealing layer, and the postprocessing device 22 can be a UV curing device or a CVD device, though they are not limited to these examples.

The preprocessing device 21 can be configured to divide one substrate into a plurality of substrates (in this example, the two substrates 2A and 2B) and process the respective substrates 2A and 2B. It is also possible to supply the divided substrates 2A and 2B to the preprocessing device 21 and to process the respective substrates 2A and 2B by the preprocessing device 21. The substrates 2A and 2B are an example of a plurality of substrates and will also be referred to as a plurality of substrates 2A and 2B hereinafter. The substrates 2A and 2B processed by the preprocessing device 21 can be mounted on a hand 23A of the substrate conveyance robot 23. At this time, the interval between the substrate 2A and the substrate 2B on the hand 23A can be adjusted in the preprocessing device 21 so as to be equal to the interval between a substrate chuck 8A and a substrate chuck 8B (to be described later). The substrate conveyance robot 23 can load the substrates 2A and 2B into the droplet placement device 1 by one operation, and the droplet placement device 1 can place droplets on the respective substrates 2A and 2B. The substrates 2A and 2B processed in the droplet placement device 1 can be unloaded from the droplet placement device 1 by one operation by the substrate conveyance robot 23 and can be loaded into the postprocessing device 22. Note that the preprocessing device 21, the substrate conveyance robot 23, the droplet placement device 1, and the postprocessing device 22 can communicate with each other via a communication channel (not shown), and communicate job information, the conveyance timing of each substrate, and information of each substrate.

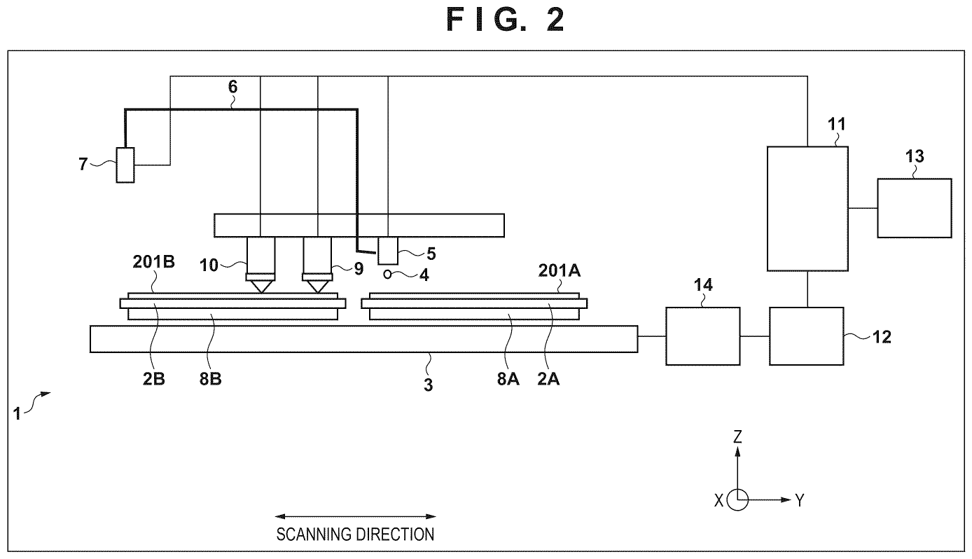

FIG. 2 schematically shows the configuration of the droplet placement device 1. In this specification and the accompanying drawings, directions are represented in an XYZ coordinate system in which a plane parallel to a plane on which the substrates 2A and 2B are arranged is defined as an X-Y plane, as shown in FIG. 2. The droplet placement device 1 can include a substrate stage (substrate holder) 3 that holds the plurality of substrates 2A and 2B. The substrate stage 3 can include the plurality of substrate chucks 8A and 8B that hold the plurality of substrates 2A and 2B, respectively. The substrates 2A and 2B can have pixel array regions 201A and 201B, respectively. The pixel array regions 201A and 201B are regions where a plurality of pixels are formed. The droplet placement device 1 can be configured to place a plurality of droplets in the respective pixel array regions 201A and 201B. A plurality of droplets may be placed to be separated from each other, at least two droplets may be placed to be combined with each other, or a plurality of droplets may be placed to form a liquid film.

The droplet placement device 1 can include a discharge head 5 that discharges droplets 4 of ink (liquid material) so as to place them at a plurality of target locations of the respective substrates 2A and 2B, an ink supply system 6 that supplies ink to the discharge head 5, and an ink tank 7 in which ink is stored. The discharge head 5 includes, for example, a plurality of nozzles two-dimensionally arranged in the X-axis direction and the Y-axis direction. Discharge of the droplets 4 from the nozzles of the discharge head 5 can be individually controlled to place the droplets 4 at a plurality of target locations in the pixel array region 201A of the substrate 2A and the pixel array region 201B of the substrate 2B.

The droplet placement device 1 can include a scanning mechanism 14 that relatively moves the substrate stage 3 with respect to the discharge head 5 so as to continuously scan the substrate stage 3 with respect to the discharge head 5. The substrate stage 3 has a configuration in which the plurality of substrates 2A and 2B are held by the plurality of substrate chucks 8A and 8B. The substrate stage 3 is continuously scanned with respect to the discharge head 5, thereby continuously scanning with respect to the discharge head 5 a region including the plurality of substrates 2A and 2B. The scanning mechanism 14 can therefore be understood as a mechanism that relatively moves the substrate stage 3 with respect to the discharge head 5 so as to continuously scan with respect to the discharge head 5 a region including the plurality of substrates 2A and 2B. Instead of moving the substrate stage 3, the discharge head 5 may be so moved as to continuously scan the substrate stage 3 with respect to the discharge head 5.

When the substrates 2A and 2B are mounted on the substrate chucks 8A and 8B on the substrate stage 3, corresponding alignment errors can be generated. After the substrates 2A and 2B undergo various manufacturing processes, shape distortions can be generated in the substrates 2A and 2B in the X-and Y-axis directions. Note that even the shape distortions of the substrates 2A and 2B generate alignment errors when the substrates 2A and 2B are mounted on the substrate chucks 8A and 8B. In this specification, errors from the ideal positions and ideal shapes of the substrates 2A and 2B in a state in which they are mounted on the substrate chucks 8A and 8B will be expressed as alignment errors. The droplet placement device 1 can include an alignment measurement device 9 for measuring the alignment errors of the substrates 2A and 2B. The alignment measurement device 9 can include a low-magnification optical system having a wide field of view for detecting an alignment mark and include a high-magnification optical system having a narrow field of view for detecting an alignment mark. The droplet placement device 1 may include a plurality of alignment measurement devices 9 in order to measure the marks of the respective substrates 2A and 2B or a plurality of marks of each substrate simultaneously or in parallel.

Since the substrates 2A and 2B can have thickness variations, the supply positions (landing positions) of the droplets 4 to the substrates 2A and 2B can vary owing to the thickness variations of the substrates 2A and 2B. Hence, the droplet placement device 1 may include a height sensor 10 that measures positions (heights) of the substrates 2A and 2B in the Z-axis direction. The results (alignment errors and heights) of measurement by the alignment measurement device 9 and the height sensor 10 can be stored in a controller 11. When the substrates 2A and 2B will be explained without distinction, they will be referred to as the substrate 2. When the pixel array regions 201A and 201B will be explained without distinction, they will be referred to as the pixel array region 201.

The controller 11 can generate, for example, discharge control information for controlling discharge of the droplets 4 to a plurality of target locations in the pixel array region 201 of the substrate 2 based on a pattern image representing the plurality of target locations (positions at which droplets should be placed). The pattern image is, for example, a two-dimensional array of data that are “1” for target locations and “0” for the remaining locations. The discharge control information can include an image in which each pixel corresponds to one droplet-suppliable coordinate, for example, a two-dimensional array of data that are “1” for target locations and “0” for the remaining locations. The controller 11 can control the discharge head 5 and the scanning mechanism 14 so as to provide the droplets 4 to a plurality of target locations of the respective substrates 2A and 2B.

The scanning mechanism 14 can control the substrate stage 3 about the X-axis, the Y-axis, the Z-axis, and the θ-axis. Here, the θ-axis is a rotation about the Z-axis. The rotation means a rotation about the θ-axis hereinafter. The droplet placement device 1 may include a stage controller 12 that operates under the control of the controller 11, and the stage controller 12 can control the substrate stage 3 about the X-axis, the Y-axis, the Z-axis, and the θ-axis. The stage controller 12 may be regarded as part of the controller 11. The controller 11 or the stage controller 12 can control the discharge head 5 and the scanning mechanism 14 so as to provide the droplets 4 to a plurality of target locations of the respective substrates 2A and 2B in a period in which the substrate stage 3 is continuously scanned by the scanning mechanism 14. The period includes, for example, an acceleration period, a constant-speed period following the acceleration period, and a deceleration period following the constant-speed period.

The droplet placement device 1 can include an interface 13. The interface 13 may be understood as a unit that manages operation information of the droplet placement device 1. Upon receiving job information from the preprocessing device 21, a high-order control device (not shown), or the like, the interface 13 can transmit the job information to the controller 11. In response to the reception of the job information from the preprocessing device 21, the high-order control device (not shown), or the like, the interface 13 may instruct the controller 11 to start the job. The interface 13 may have a function of receiving information representing the placement locations of a plurality of droplets to the substrates 2A and 2B and information about alignment of the substrates 2A and 2B, or editing such information.

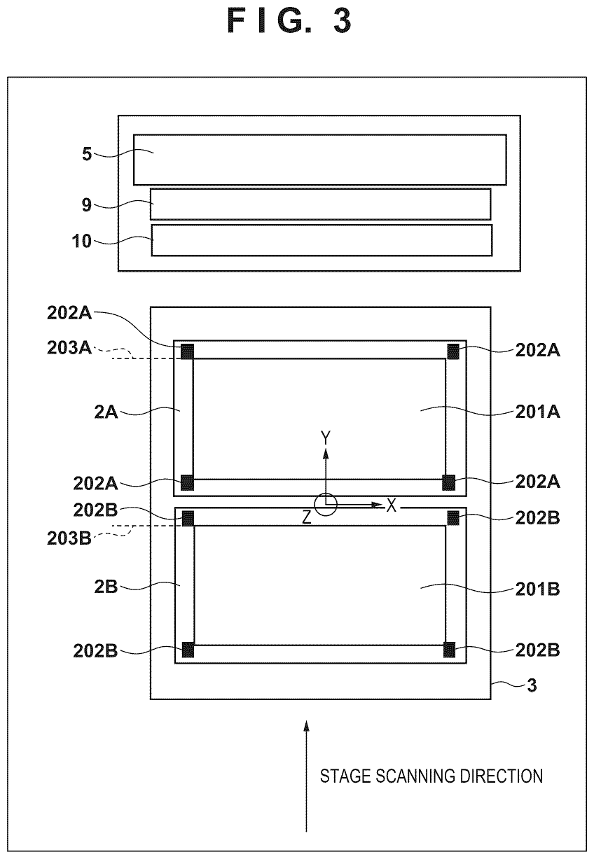

FIG. 3 is a schematic view of the substrate stage 3 when viewed from the top. FIG. 3 shows the substrates 2A and 2B mounted on the substrate chucks 8A and 8B. The substrate 2A has the pixel array region 201A and alignment marks 202A. The substrate 2B has the pixel array region 201B and alignment marks 202B. The pixel array regions 201A and 201B have a plurality of pixels, and each pixel can have subpixels, such as R, G, and B subpixels. At least one substrate out of the plurality of substrates 2A and 2B may have a plurality of pixel array regions arranged to be spaced apart from each other.

FIG. 3 schematically shows a state in which the substrate stage 3 is scanned in a positive direction along the Y-axis. A position 203A on the substrate 2A is a position where placement, application, or discharge of droplets to the pixel array region 201A starts. A position 203B on the substrate 2B is a position where placement, application, or discharge of droplets to the pixel array region 201B starts. When the substrate stage 3 is scanned in a negative direction along the Y-axis, the positions 203A and 203B are changed to other positions.

In the example shown in FIG. 3, four alignment marks 202A are provided on the substrate 2A, and four alignment marks 202B are provided on the substrate 2B. However, the number of alignment marks provided on each substrate suffices to be two or more. Needless to say, a larger number of alignment marks can be provided to measure the deformation of a substrate at higher accuracy. When four alignment marks are provided on each substrate, shift components SX, SY, and Sθ; magnification components MX and MY; and distortion components DR and Yaw can be measured as alignment errors.

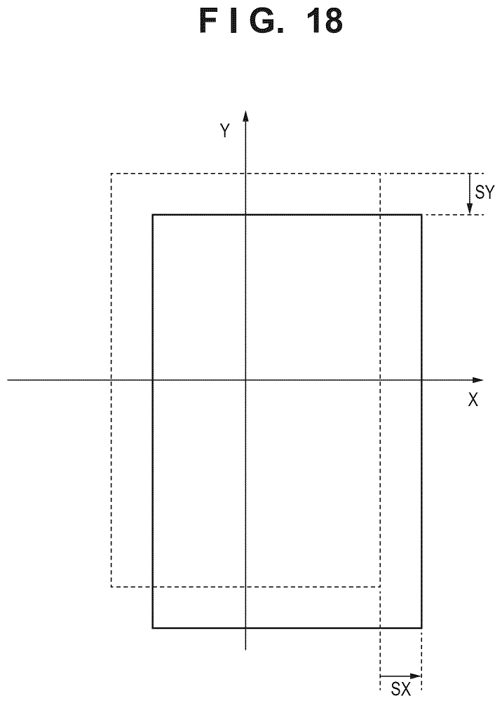

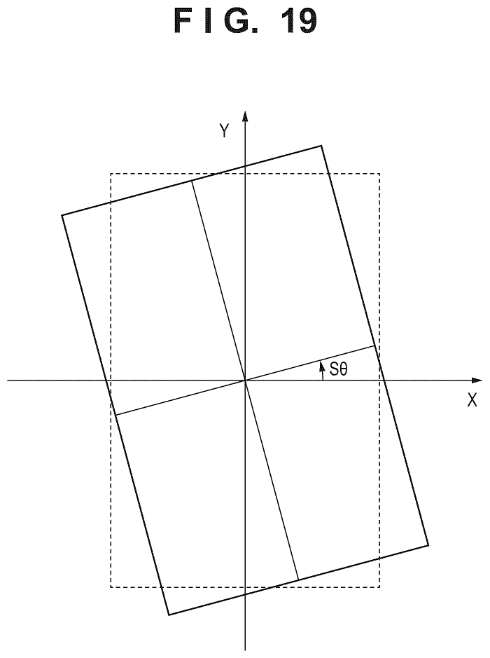

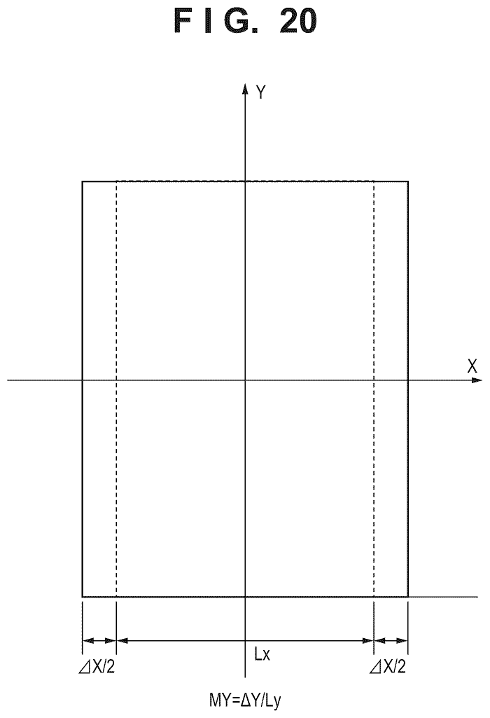

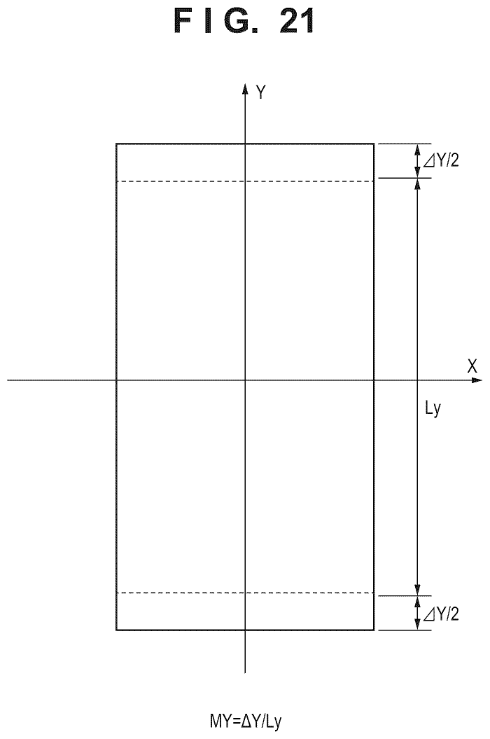

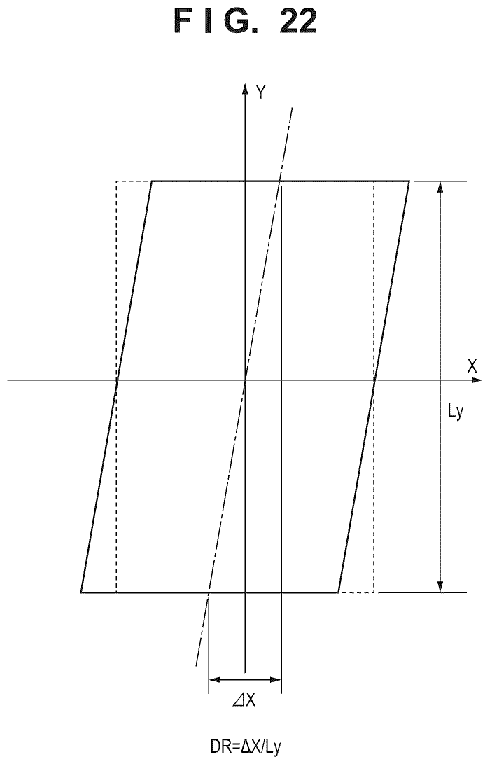

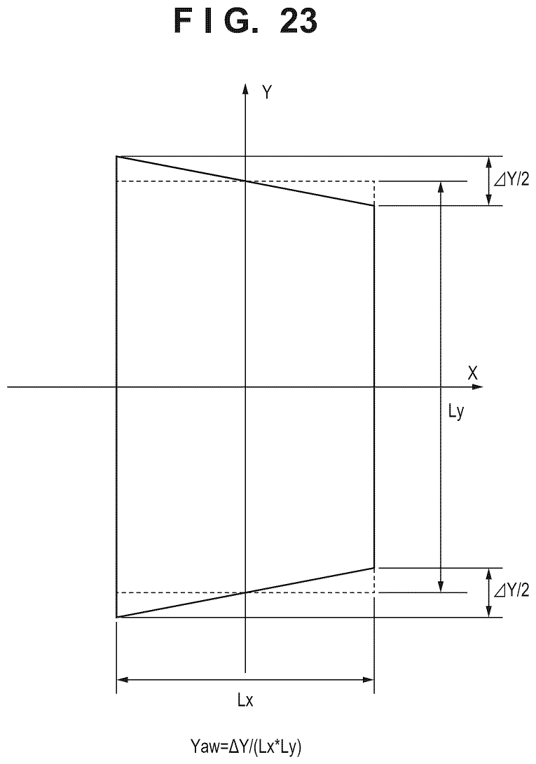

The components of alignment errors will be explained with reference to FIGS. 18 to 23. In FIGS. 18 to 23, a dotted line represents an ideal shape, and a dotted line represents a shape having an alignment error. FIG. 18 exemplifies the shift components SX and SY. FIG. 19 exemplifies the shift component Sθ. FIG. 20 exemplifies the magnification component MX. FIG. 21 exemplifies the magnification component MY. FIG. 22 exemplifies the distortion component DR. FIG. 23 exemplifies the distortion component Yaw.

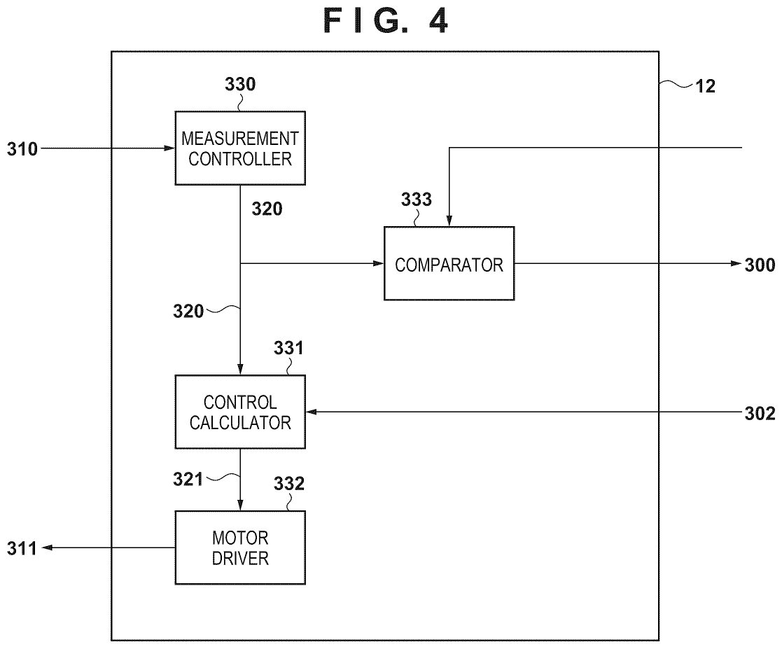

FIG. 4 is a functional block diagram of the stage controller 12. The stage controller 12 controls the substrate stage 3 by controlling the scanning mechanism 14. The stage controller 12 can be constituted by one or a plurality of processors. A measurement device signal 310 is a signal provided from a measurement device (not shown), such as a laser interferometer or an encoder, and is, for example, a pulse signal corresponding to the position of the substrate stage 3. The measurement device signal 310 can include a plurality of signals for the respective axes of the substrate stage 3.

A measurement controller 330 can count, for example, pulses of the measurement device signal 310, convert them into a stage position 320 representing the position of the substrate stage 3, and provide the stage position 320 to a control calculator 331 and a comparator 333 in a predetermined cycle. The control calculator 331 can perform compensation calculation based on the deviation between a target driving position 302 and the current stage position 320, generate a control output 321, and provide it to a motor driver 332. The compensation calculation is, for example, a PID calculation. The motor driver 332 generates a motor current 311 for driving the motor of the scanning mechanism 14 in accordance with the control output 321 and supplies the motor current 311 to the motor. The motor is, for example, a servo motor. By this configuration, the substrate stage 3 can be feedback-controlled.

The comparator 333 is a device that monitors the position of the substrate stage 3. The comparator 333 compares the current stage position 320 with a first discharge start position 301A and a second discharge start position 301B that are provided from the controller 11. When the stage position 320 and the first discharge start position 301A coincide with each other, the comparator 333 outputs a discharge start signal (first discharge start signal) 300. Also, when the stage position 320 and the second discharge start position 301B coincide with each other, the comparator 333 outputs a discharge start signal (second discharge start signal) 300. In the example of FIG. 3, the comparator 333 outputs the discharge start signal 300 in response to the coincidence between the stage position 320 and the first discharge start position 301A, and then the comparator 333 outputs the discharge start signal 300 in response to the coincidence between the stage position 320 and the second discharge start position 301B. Outputting the discharge start signal 300 can mean that the level of a signal line for transmitting the discharge start signal 300 is changed to an active level. Also, outputting the discharge start signal 300 can mean that a command is output to the signal line for transmitting the discharge start signal 300.

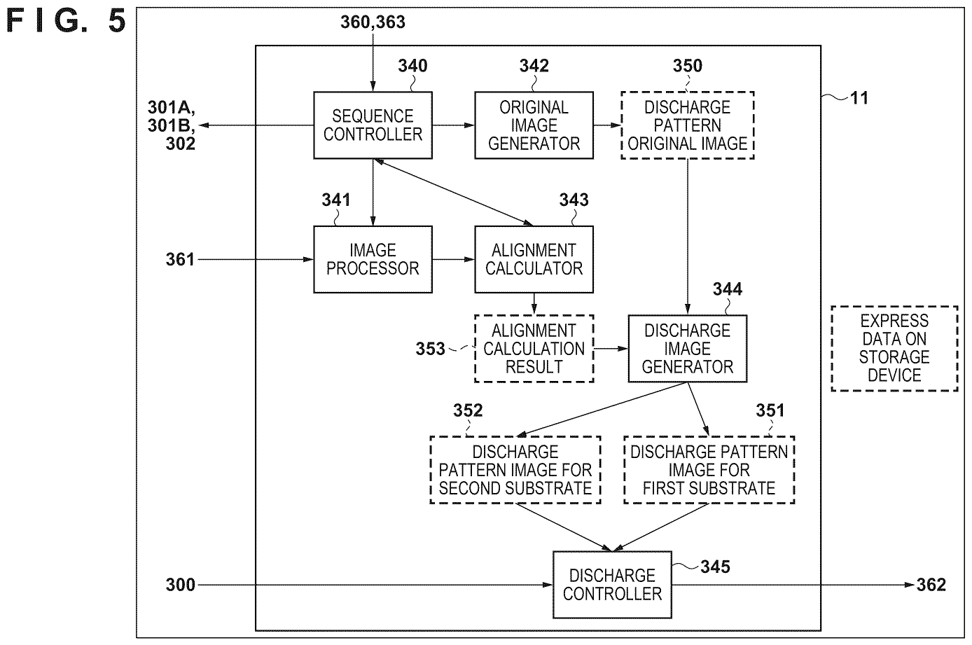

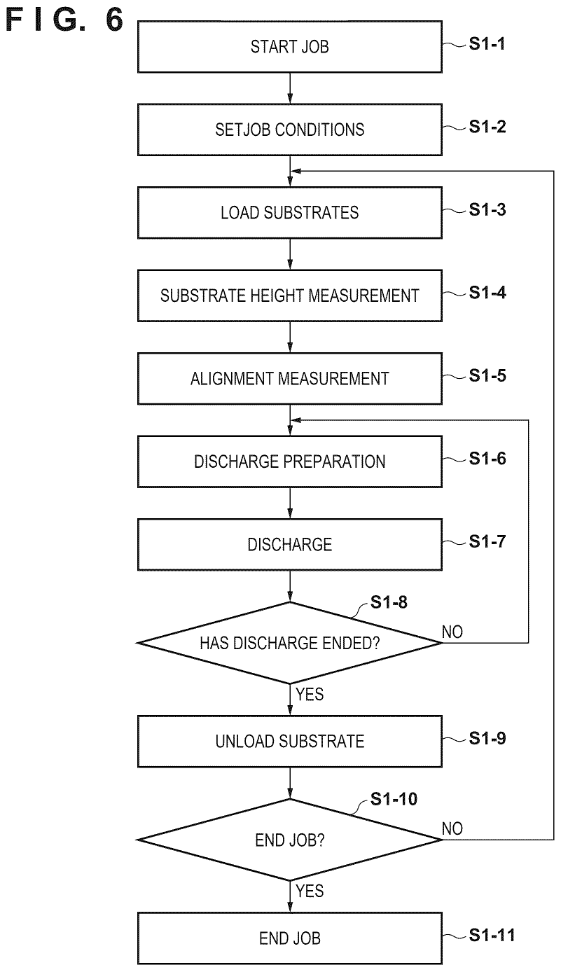

FIG. 5 is a functional block diagram of the controller 11. The controller 11 can be constituted by one or a plurality of processors. Job data 363 and a job start signal 360 are provided from the interface 13. Upon receiving the job start signal 360, a sequence controller 340 starts a processing sequence. The operation of the sequence controller 340 will be described later with reference to the flowchart of FIG. 6.

An image processor 341 obtains images generated by capturing the alignment marks 202A and 202B respectively provided on the substrates 2A and 2B by the alignment measurement device 9. Then, the image processor 341 calculates the shift amounts of the alignment marks 202A and 202B from the reference positions of the alignment marks 202A and 202B based on information of feature points registered in advance. The processing of calculating the shift amount of an alignment mark can include coarse measurement processing (Pre measurement) using the low-magnification optical system of the alignment measurement device 9 and can include fine detection processing (Fine measurement) using the high-magnification optical system.

An alignment calculator 343 calculates a plurality of components of alignment errors of the substrates 2A and 2B based on the shift amounts of respective alignment marks calculated by the image processor 341. The plurality of components can be the shift components SX, SY, and Sθ, the magnification components MX and MY, and the distortion components DR and Yaw. The plurality of components of the alignment errors calculated by the alignment calculator 343 are stored as an alignment calculation result 353 in a storage device.

An original image generator 342 generates a discharge pattern original image 350 as an original image for controlling discharge of droplets from the discharge head 5. More specifically, the original image generator 342 converts data whose unit is a length, such as the size or resolution, of the pixel array region 201A or 201B designated by the job data 363, into data whose unit is a time regarding the discharge timing of every droplet. That is, the original image generator 342 generates data regarding a time obtained by dividing the placement position (landing position) of each droplet by the scanning speed. The generated data can include a discharge frequency, an inter-discharge delay, and the like, and may also include waveform data representing a waveform supplied to the driving element of each nozzle of the discharge head 5 at the time of droplet discharge. These data are stored as the discharge pattern original image 350 in the storage device. Note that data generated by the original image generator 342 is data of a discharge timing representing an ideal pixel array region shape not including the placement error of a substrate, the deformation of a substrate caused by a process, and the like.

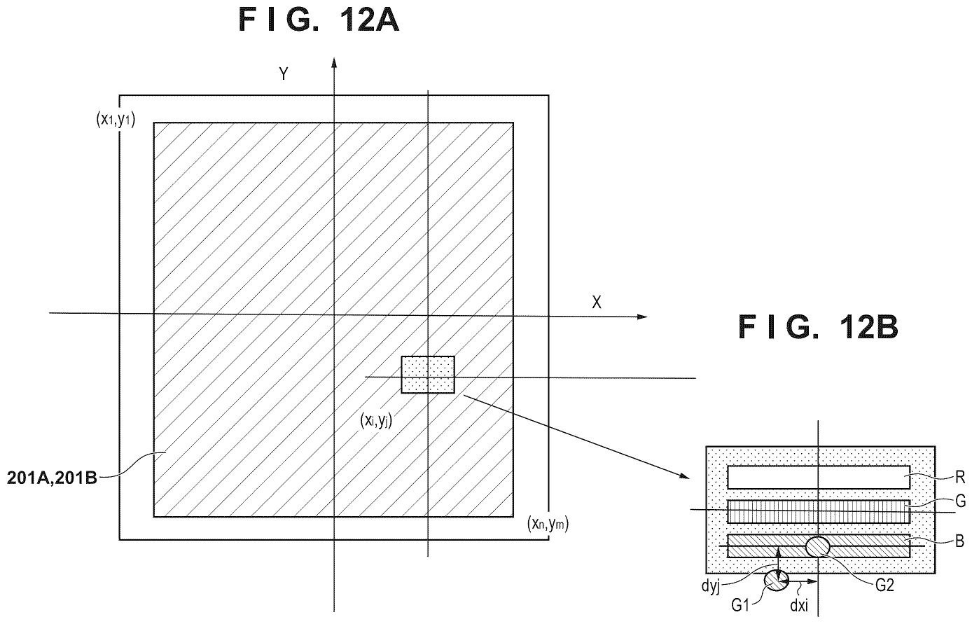

A discharge image generator 344 converts the discharge pattern original image 350 serving as a discharge timing of each pixel array region into a discharge timing of each substrate, and the discharge image generator 344 corrects the discharge timing of each substrate based on the alignment calculation result 353. The correction based on the alignment calculation result 353 can be performed for each pixel or each group of pixels. An alignment error of each pixel in the Y-axis direction serving as a scanning direction can be corrected by adjusting the discharge timing, and an alignment error in the X-axis direction serving as a non-scanning direction can be corrected by selecting the position of the substrate stage 3 in the X-axis direction and/or the nozzle of the discharge head 5. The discharge image generator 344 generates a first discharge pattern image 351 for the first substrate 2A and a second discharge pattern image 352 for the second substrate 2B, and the discharge image generator 344 stores them in the storage device. Details of the discharge image generator 344 will be described later with reference to FIGS. 12A and 12B.

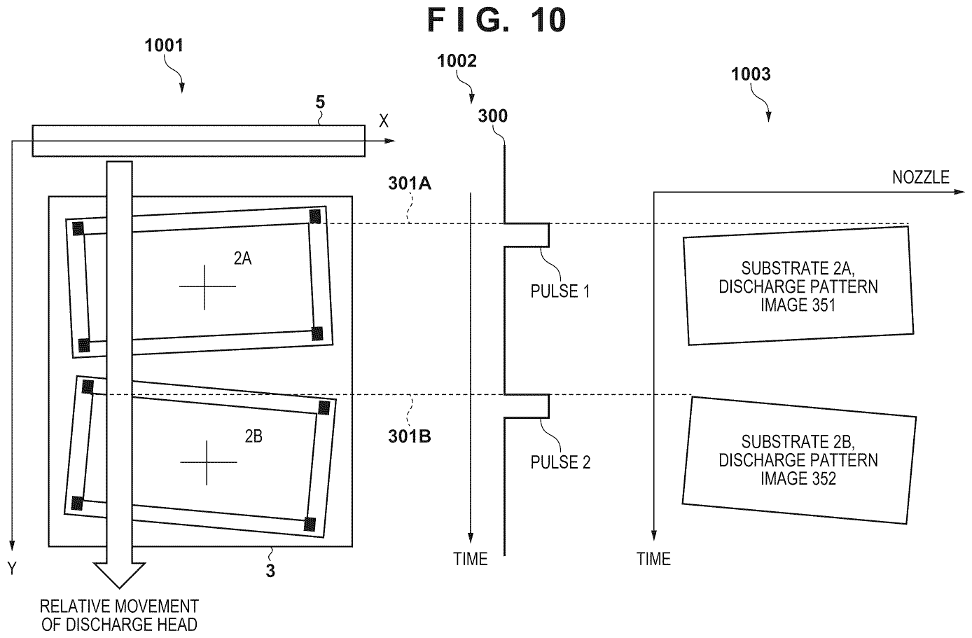

A discharge controller 345 supplies a discharge control signal 362 to the discharge head 5. The discharge controller 345 generates the discharge control signal 362 based on the first discharge pattern image 351 for the first substrate 2A and the second discharge pattern image 352 for the second substrate 2B. In accordance with the discharge start signal 300, the discharge controller 345 can switch which of the first discharge pattern image 351 for the first substrate 2A and the second discharge pattern image 352 for the second substrate 2B the discharge control signal 362 is generated based on. When the substrate stage 3 is scanned in the positive direction along the Y-axis, as exemplified in FIG. 3, droplets are applied (printed) in the order of the substrate 2A and the substrate 2B. In accordance with the discharge start signal 300, the discharge controller 345 switches from the first discharge pattern image 351 for the first substrate 2A to the second discharge pattern image 352 for the second substrate 2B. In contrast, when the scanning direction is the negative direction along the Y-axis, droplets are applied (printed) in the order of the substrate 2B and the substrate 2A. In accordance with the discharge start signal 300, the discharge controller 345 switches from the second discharge pattern image 352 for the second substrate 2B to the first discharge pattern image 351 for the first substrate 2A. A detailed example of the switching will be explained later with reference to FIG. 10.

FIG. 6 is a flowchart showing the operation sequence of the droplet placement device 1. This operation sequence is controlled by the sequence controller 340. In step S1 1, the sequence controller 340 receives the job data 363 and the job start signal 360 from the interface 13, and the sequence controller 340 starts a job in response to them. In step S1-2, the sequence controller 340 instructs the original image generator 342 to generate the discharge pattern original image 350. Based on the job data 363, the sequence controller 340 sets a scanning count necessary to complete the placement of droplets onto the substrates 2A and 2B. When the scanning count is a plurality of times, the sequence controller 340 controls the discharge head 5 and the scanning mechanism 14 so as to complete discharge of droplets to the plurality of substrates 2A and 2B in a plurality of scans by the scanning mechanism 14.

In step S1-3, the sequence controller 340 controls the substrate conveyance robot 23 to load the substrates 2A and 2B into the droplet placement device 1. In one example, the substrates 2A and 2B are held by the hand 23A of the substrate conveyance robot 23 at the same interval as that between the substrate chucks 8A and 8B in the Y-axis direction and are transferred onto the substrate chucks 8A and 8B via a substrate transfer mechanism (not shown). When transferring the substrates 2A and 2B, corresponding placement errors are generated for the respective substrates 2A and 2B, so alignment errors need to be corrected for the respective substrates 2A and 2B.

In step S1-4, the sequence controller 340 measures the heights of the substrates 2A and 2B using the height sensor 10. In one example, the sequence controller 340 measures, using the height sensor 10, heights of the substrates 2A and 2B at measurement positions on the substrates 2A and 2B that are set by the job data 363. Note that it is also possible to measure heights of each substrate 2 at a plurality of measurement positions, and set the average of the obtained measurement values as the height of the substrate 2.

When measuring heights of the respective substrates 2A and 2B at one measurement position, the position correction amounts of the substrates 2A and 2B in the Z-axis direction can be obtained by the following equation. Let H be the ideal height of the substrates 2A and 2B expected to be measured by the height sensor 10, Ha be the height measurement value of the substrate 2A actually measured by the height sensor 10, Hb be the height measurement value of the substrate 2B, and vd be the speed of the droplet 4. Then, a correction amount dZa of the substrate 2A in the Z-axis direction of the substrate stage 3 is given by

dZa=Ha−H.

If a height difference exists between substrates 2A and 2B upon correcting the correction amount of the substrate 2A in the Z-axis direction along the Z-axis of the substrate stage 3, the height of the substrate 2B is corrected by adjusting the delay time of the discharge timing of the droplet 4 from the discharge head 5 based on the height difference between substrates 2A and 2B. A correction delay time DelayZb of the substrate 2B in the Z-axis direction is given by

DelayZb=((Hb−H)-dZa)/vd.

The calculation result can be provided to the alignment calculator 343 so that correction processing is performed together with the alignment error component of another axis.

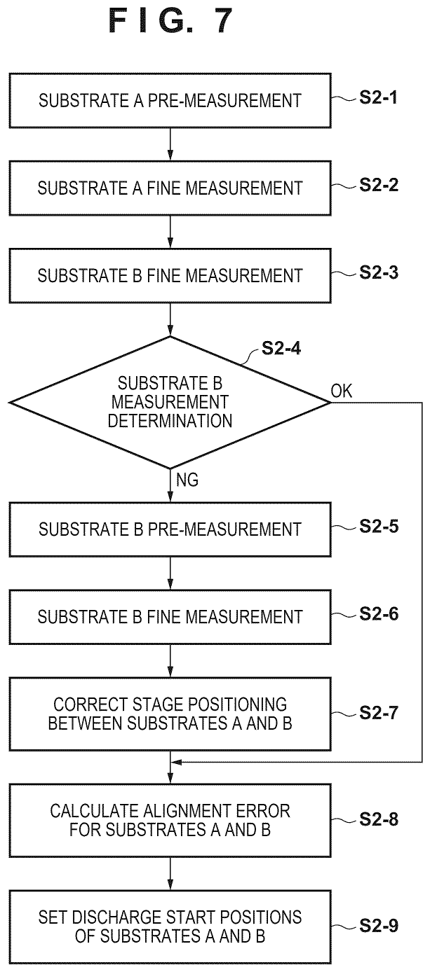

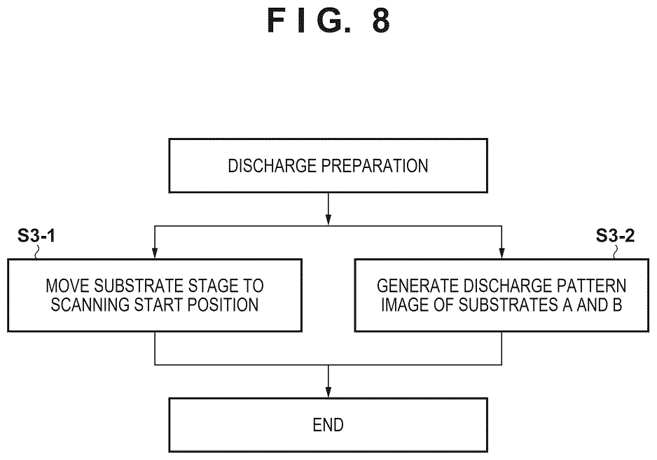

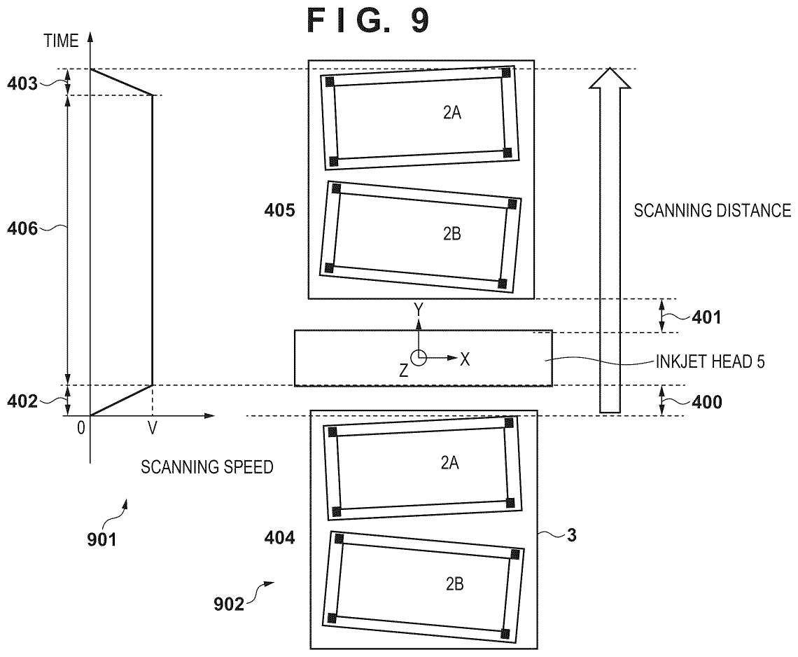

In step S1-5, the sequence controller 340 executes the measurement sequence of the alignment errors of the substrates 2A and 2B. Details of the alignment error measurement sequence will be explained later with reference to the flowchart of FIG. 7. In step S1-6, the sequence controller 340 performs droplet discharge preparation on the substrates 2A and 2B. Details of this processing will be explained later with reference to FIG. 8. In step S1-7, the sequence controller 340 performs droplet discharge processing (location processing) on the substrates 2A and 2B. Details of this processing will be explained later with reference to FIGS. 8 and 9. In step S1-8, the sequence controller 340 determines whether scanning at the scanning count set in step S1-2 has ended. If the scanning has not ended, the sequence controller 340 repeats steps S1-6 and S1-7; if it has ended, the sequence controller 340 advances to step S1-9.

In step S1-9, the sequence controller 340 controls the substrate conveyance robot 23 to unload the substrates 2A and 2B from the droplet placement device 1. The unloaded substrates 2A and 2B are conveyed to the postprocessing device 22 by the substrate conveyance robot 23.

In step S1-10, the sequence controller 340 determines whether the processing designated by the job data has ended. If the processing has not ended, the sequence controller 340 returns to step S1-3; if it has ended, the sequence controller 340 advances to step S-11 to end the job.

The alignment error measurement sequence (step S1-5) will be explained with reference to FIG. 7. The alignment error measurement sequence can be executed by the sequence controller 340 using the image processor 341 and the alignment calculator 343 of the controller 11. In step S2-1, the sequence controller 340 executes coarse measurement processing (Pre measurement) using the low-magnification optical system of the alignment measurement device 9. In the coarse measurement processing, first, the sequence controller 340 moves the substrate stage 3 to a position where the alignment marks 202A of the substrate 2A can be observed by the alignment measurement device 9. At this time, the placement error of the substrate 2A in mounting on the substrate stage 3 is not considered. Hence, the sequence controller 340 captures the alignment marks 202A in a wide range on the substrate 2A using the low-magnification optical system of the alignment measurement device 9. The image processor 341 processes the captured image to calculate the shift amount of the substrate 2A. Further, the sequence controller 340 corrects positions of the substrate stage 3 about the X-axis, the Y-axis, and the θ-axis based on the calculated shift amount. The substrate stage 3 is driven by setting the target driving position 302 for the stage controller 12. As a result, the alignment marks 202A can be observed by the high-magnification optical system of the alignment measurement device 9.

In step S2-2, the sequence controller 340 executes fine measurement processing (Fine measurement) using the high-magnification optical system of the alignment measurement device 9. In the fine measurement processing, the sequence controller 340 captures the alignment marks 202A of the substrate 2A by the high-magnification optical system of the alignment measurement device 9, and the image processor 341 calculates a precise value of the shift amount of each alignment mark of the substrate 2A based on the captured image.

In step S2-3, the sequence controller 340 executes fine measurement processing (Fine measurement) on the substrate 2B using the high-magnification optical system of the alignment measurement device 9. More specifically, first, the sequence controller 340 moves the substrate stage 3 to a position where the alignment marks 202B of the substrate 2B can be observed by the alignment measurement device 9. Then, the sequence controller 340 captures the alignment marks 202B of the substrate 2B by the high-magnification optical system of the alignment measurement device 9, and the image processor 341 calculates a precise value of the shift amount of each alignment mark of the substrate 2B based on the captured image. Note that when the droplet placement device 1 includes a plurality of alignment measurement devices so that the alignment marks 202A and 202B of the substrates 2A and 2B can be simultaneously observed, steps S2-2 and S2-3 may be executed in parallel.

In step S2-4, the sequence controller 340 determines the result of image processing by the image processor 341 in the fine measurement processing in step S2-3. If the result of image processing is OK, that is, if the shift amount of the alignment mark 202B of the substrate 2B has been measured appropriately, the sequence controller 340 advances to step S2-8; if NG, to step S2-5. A reason why the shift amount of the alignment mark 202B of the substrate 2B has not been measured appropriately is that the shift amount of the substrate 2B with respect to the substrate 2A is too large and the alignment mark 202B does not fall within the field of view (image capturing range) of the high-magnification optical system.

In step S2-5, the sequence controller 340 executes coarse measurement processing (Pre measurement) on the alignment marks 202B of the substrate 2B using the low-magnification optical system of the alignment measurement device 9. More specifically, the sequence controller 340 captures the alignment marks 202B of the substrate 2B using the low-magnification optical system of the alignment measurement device 9. The image processor 341 processes the captured image to calculate the shift amount of the substrate 2B. Further, the sequence controller 340 corrects positions of the substrate stage 3 about the X-axis, the Y-axis, and the θ-axis based on the calculated shift amount. Therefore, the alignment marks 202B can be observed by the high-magnification optical system of the alignment measurement device 9.

In step S2-6, the sequence controller 340 executes fine measurement processing (Fine measurement) on the alignment mark 202B of the substrate 2B using the high-magnification optical system of the alignment measurement device 9. In the fine measurement processing, the sequence controller 340 captures the alignment marks 202B of the substrate 2B by the high-magnification optical system of the alignment measurement device 9, and the image processor 341 calculates a precise value of the shift amount of each alignment mark of the substrate 2B based on the captured image.

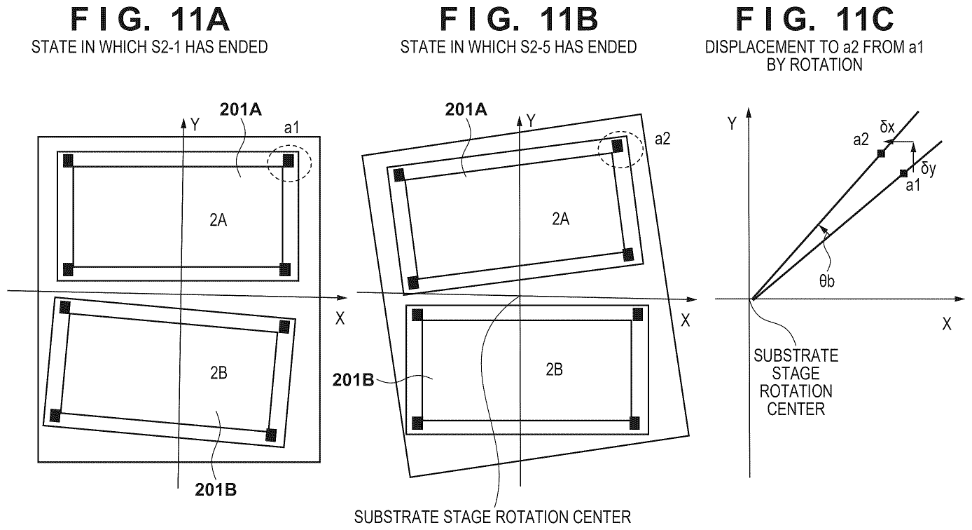

In step S2-7, the sequence controller 340 calculates the relative positions of the substrates 2A and 2B. Since the substrate stage 3 is driven in step S2-5, the shift amount calculation result of the substrate 2A calculated in step S2-2 changes. It therefore becomes necessary to subtract, from the calculation result of the shift amount of the substrate 2A calculated in step S2-2, an amount equivalent to the amount by which the substrate stage 3 has been driven in step S2-5. Details of this processing will be explained below with reference to FIGS. 11A to 11C.

In step S2-8, the sequence controller 340 calculates the respective components of the alignment errors of the substrates 2A and 2B using the alignment calculator 343. Here, assume that the alignment calculator 343 calculates the shift components SX, SY, and Sθ, the magnification components MX and MY, and the distortion component DR as components (linear shift components) of the alignment errors. Letting (x, y) be the measurement result of the position of the alignment mark 202, and (dx, dy) be the shift amount of the alignment mark 202 with reference to an ideal position, a model given by the following equations (1) and (2) is established:

dy=SY+MY·y−θ·x, (1) and

dx+θ·y=SX+DR·y−MX·x (2)

For this model, if the alignment marks 202 are measured at at least three points, then six equations having linear shift components as variables are obtained. These equations can be solved as simultaneous equations, obtaining linear shift components. If there are four or more alignment mark measurement points, linear shift components may be calculated by the method of least mean squares. These calculations are performed for the respective substrates 2A and 2B, and linear shift components SX, SY, Sθ, MX, MY, and DR are stored as the alignment calculation results 353 in the storage device for the respective substrates 2A and 2B.

Note that the substrate 2B is corrected based on the correction delay time DelayZb of the substrate 2B in the Z-axis direction that is obtained in step S1-4.

In step S2-9, the sequence controller 340 calculates the first discharge start position 301A and the second discharge start position 301B. Let Pa and Pb be positions of the substrate stage 3 when the positions 203A and 203B shown in FIG. 3 coincide with predetermined positions of the discharge head 5 in the Y-axis direction, respectively. Positions of the substrate stage 3 when the discharge start signal 300 is emitted are obtained by adding SYa and SYb, which are SY calculated for the respective substrates 2A and 2B, to Pa and Pb in accordance with equation (1), and can be given by the following equations:

first discharge start position 301A=Pa+SYa, and

second discharge start position 301B=Pb+SYb.

The first discharge start position 301A and the second discharge start position 301B are set in the comparator 333 of the stage controller 12.

The droplet discharge preparation sequence (step S1-6) will be explained below with reference to FIG. 8. In step S3-1, the sequence controller 340 moves the substrate stage 3 to a scanning start position. The scanning start position is exemplified as a scanning start position 404 in FIG. 9. In step S3-2, the sequence controller 340 generates the discharge pattern image 351 for the first substrate 2A and the discharge pattern image 352 for the second substrate 2B based on the discharge pattern original image 350 and the alignment calculation result 353 using the discharge image generator 344. The discharge pattern image generation method will be described later with reference to FIGS. 12A and 12B. Steps S3-1 and S3-2 can be executed in parallel to shorten the processing time.

FIG. 9 schematically shows the operation of the substrate stage 3 in droplet placement processing (print processing) of placing droplets onto the substrates 2A and 2B. In FIG. 9, reference numeral 901 denotes a speed profile of the substrate stage 3, and reference numeral 902 schematically denotes a move of the substrate stage 3. The substrate stage 3 is continuously scanned from the scanning start position 404 to a scanning end position 405. In the example of FIG. 9, the substrate stage 3 is scanned in the positive direction along the Y-axis. A period in which the substrate stage 3 is continuously scanned from the scanning start position 404 to the scanning end position 405 includes an acceleration period 402, a constant-speed period 406 following the acceleration period 402, and a deceleration period 403 following the constant-speed period 406. In the constant-speed period 406, the controller 11 can control the discharge head 5 and the scanning mechanism 14 so as to provide droplets to the respective substrates 2A and 2B. The controller 11 can move the substrate stage 3 along a straight line (straight line parallel to the Y-axis) in the period in which the substrate stage 3 is continuously scanned from the scanning start position 404 to the scanning end position 405.

An acceleration distance 400 is a distance by which the substrate stage 3 moves in the acceleration period 402. Letting V be the scanning speed as a speed of the substrate stage 3 in the constant-speed period 406, and A be the acceleration of the substrate stage 3 in the acceleration period 402, the acceleration distance 400 can be given by the following equation:

acceleration distance 400=1/(2*A)*V².

A deceleration distance 401 can also be obtained similarly.

When the scanning direction is opposite, that is, when the substrate stage 3 is operated in the negative direction along the Y-axis, it suffices to interchange the deceleration distance 401 and the acceleration distance 400.

When scanning starts at time 0, the speed of the substrate stage 3 reaches a predetermined scanning speed V upon the lapse of the acceleration period 402. At the end of the constant-speed period 406, deceleration starts, and the substrate stage 3 stops upon the lapse of the deceleration period 403. For example, the acceleration period 402 can be obtained as follows from the relationship between the scanning speed V and the acceleration A. Assuming that the acceleration A is constant, the acceleration period 402 can be given by the following equation:

acceleration period 402=V/A.

The deceleration period 403 can also be obtained similarly.

The control calculator 331 of the stage controller 12 controls driving of the substrate stage 3 by the above-described driving pattern.

FIG. 10 is a view schematically showing control of the substrate stage 3 by the discharge controller 345 of the controller 11. In FIG. 10, reference numeral 1001 denotes a relative positional relationship between (i) the substrates 2A and 2B mounted on the substrate stage 3 and (ii) the discharge head 5. The discharge head 5 relatively moves down in FIG. 10 with respect to the substrate stage 3 to place (print) droplets in the order of the substrate 2A and the substrate 2B. Discharge of droplets to the substrate 2A starts at the first discharge start position 301A, and discharge of droplets to the substrate 2B starts at the second discharge start position 301B. The first discharge start position 301A and the second discharge start position 301B are set in step S2-9.

In FIG. 10, reference numeral 1002 denotes the discharge start signal 300. Activation of the discharge start signal 300 is represented by pulse 1 and pulse 2. Pulse 1 and pulse 2 are generated by the comparator 333. Pulse 1 is emitted (generated) at a timing when the substrate stage 3 reaches the first discharge start position 301A, and pulse 2 is emitted (generated) at a timing when the substrate stage 3 reaches the second discharge start position 301B. Note that pulse 1 and pulse 2 are shown as signals output to one signal line in FIG. 10, but may be transmitted to different signal lines.

In FIG. 10, reference numeral 1003 schematically denotes the first discharge pattern image 351 for the first substrate 2A and the second discharge pattern image 352 for the second substrate 2B. The first discharge pattern image 351 for the first substrate 2A is the first discharge control information for controlling discharge of droplets from the discharge head 5. The second discharge pattern image 352 for the second substrate 2B is the second discharge control information for controlling discharge of droplets from the discharge head 5. When pulse 1 is emitted, discharge of droplets starts from the discharge head 5 in accordance with the first discharge pattern image 351 for the first substrate 2A. Subsequently, the substrate stage 3 progresses, and when pulse 2 is emitted, discharge of droplets starts from the discharge head 5 in accordance with the second discharge pattern image 352 for the second substrate 2B. The discharge controller 345 outputs the discharge control signal 362 according to the discharge pattern images 351 and 352. Then, discharge of droplets from the discharge head 5 is controlled in accordance with the alignment errors of the plurality of substrates 2A and 2B so as to provide droplets to a plurality of target locations of the respective substrates 2A and 2B.

As exemplified in FIGS. 9 and 10, the period in which the region including the plurality of substrates 2A and 2B is continuously scanned with respect to the discharge head 5 can include the first period in which the first substrate 2A is scanned by the scanning mechanism 14 and include the second period in which the second substrate 2B is scanned by the scanning mechanism 14. By this control, the placement of droplets onto the plurality of substrates 2A and 2B can be efficiently performed to improve the throughput. The controller 11 (discharge image generator 344) can generate the first discharge control information for controlling discharge of droplets to a plurality of target locations of the first substrate 2A and generate the second discharge control information for controlling discharge of droplets to a plurality of target locations of the second substrate 2B. The controller 11 (discharge controller 345) can control the discharge head 5 based on the first discharge control information in the first period and can control the discharge head 5 based on the second discharge control information in the second period.

The controller 11 or the stage controller 12 can generate the first discharge start signal 300 representing the start of discharge of droplets to the first substrate 2A and generate the second discharge start signal 300 representing the start of discharge of droplets to the second substrate 2B. The discharge head 5 can start discharge of droplets to the first substrate 2A based on the first discharge start signal 300 and can start discharge of droplets to the second substrate 2B based on the second discharge start signal 300. From another viewpoint, the controller 11 or the stage controller 12 can control the discharge head 5 so as to adjust the start timing of discharge of droplets to the first substrate 2A in accordance with the alignment error of the first substrate 2A. Also, the controller 11 or the stage controller 12 can control the discharge head 5 so as to adjust the start timing of discharge of droplets to the second substrate 2B in accordance with the alignment error of the second substrate 2B.

FIGS. 11A to 11C are views showing the relationship between the alignment marks of the substrates 2A and 2B and the substrate stage 3. FIGS. 11A to 11C show that there is a rotational error between the substrate 2A and the substrate 2B about the θ-axis. FIG. 11A shows a state in which step S2-1 in FIG. 7 ends. In the state of FIG. 11A, the substrate stage 3 is driven about the θ-axis (that is, driven to rotate) so that the pixel array region 201A of the substrate 2A does not have a rotational error in the scanning direction.

FIG. 11B shows a state in which step S2-5 in FIG. 7 ends. In the state of FIG. 11B, the substrate stage 3 is driven about the θ-axis (that is, driven to rotate) so that the pixel array region 201B of the substrate 2B does not have a rotational error in the scanning direction. Here, focusing on the upper right alignment mark of the substrate 2A, the alignment mark moves from a position a1 to a position a2.

FIG. 11C shows a change from the position a1 to the position a2 by rotation of the substrate stage 3. Letting θb be the driving amount (rotation amount) of the substrate stage 3 about the θ-axis in step S2-5, a displacement amount (δx, δy) of the alignment mark from the state at the position a1 to the state at the position a2 can be obtained. By using this, the relative positions of the substrates 2A and 2B can be calculated in step S2-7.

FIGS. 12A and 12B are views for explaining processing of reflecting the alignment calculation result 353 in each pixel. FIG. 12A is a view showing the pixel array region 201A or 201B and the position of each pixel. Each pixel includes R, G, and B subpixels as shown in FIG. 12B, which is a partially enlarged view of FIG. 12A. Here, a position G1 is a predicted landing position before correcting an alignment error, and a position G2 is a target landing position. By correcting an alignment error (dxᵢ, dyⱼ), a droplet can be placed at the target landing position.

A method of calculating the alignment error of a pixel will be explained below. In FIG. 12A, (x₁, y₁) is the coordinates of an upper left pixel of the pixel array region 201, (xₙ, yₘ) is the coordinates of a lower right pixel of the pixel array region 201, and (xᵢ, yⱼ) is the coordinates of an arbitrary pixel. The alignment error (dxᵢ, dyⱼ) at the arbitrary coordinates (xᵢ, yⱼ) can be obtained by substituting the coordinates (xᵢ, yⱼ) and the alignment calculation result 353 (SX, SY, Sθ, MX, MY, and DR) into equations (1) and (2). The substituted equations are as follows:

dyⱼ=SY+MY·yⱼ−θ·xᵢ, (3)and

dxᵢ+θ·yⱼ=SX+DR·yⱼ−MX·xᵢ. (4)

Here, the alignment error dyⱼ in the scanning direction (Y-axis direction) can be adjusted by the discharge timing of the droplet 4, and it suffices to convert the alignment error into a delay value by time unit. Letting Dⱼ be the delay time of the coordinates (xᵢ, yⱼ) of a pixel, the delay time Dⱼ is given by equation (5) because the substrate stage 3 is driven at the scanning speed V:

Dⱼ=dyⱼ/V. (5)

The Dⱼ value is equivalent to the integrated value of delay times from a pixel of coordinates (xᵢ, y₁) to a pixel of coordinates (xᵢ, yⱼ) in the scanning period. In actual correction, the delay time needs to be adjusted between pixels in the Y-axis direction. Hence, letting ΔDⱼ be the delay time between a pixel of coordinates (xᵢ, yⱼ₋₁) and a pixel of coordinates (xᵢ, yⱼ), ΔDⱼ is given by equation (6):

ΔDⱼ=Dⱼ−Dⱼ₋₁. (6)

Based on ΔDⱼ, the delay time between pixels can be set.

If delay times are individually calculated for all pixels to greatly increase the calculation amount, and the prolongation of the calculation time affects the takt time, it is also possible to calculate the alignment error dyⱼ for every group of a predetermined number of pixels, and calculate the delay time ΔDⱼ based on this.

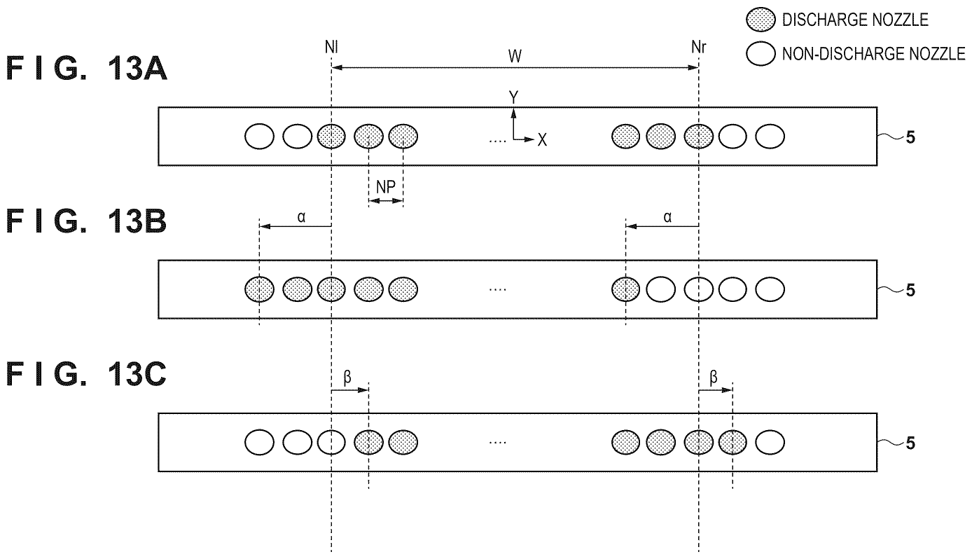

FIGS. 13A to 13C show the relationship between an alignment error in the X-axis direction (non-scanning direction) and a use nozzle. In FIGS. 13A to 13C, a hatched circle represents a discharge nozzle from which a droplet is discharged among a plurality of nozzles of the discharge head 5, and a blank circle represents a non-discharge nozzle from which no droplet is discharged among the plurality of nozzles of the discharge head 5. Assume that respective nozzles are numbered in the order from first. The respective nozzles are aligned at a pitch NP in the X-axis direction.

FIG. 13A exemplifies assignment of discharge nozzles and non-discharge nozzles according to the discharge pattern original image 350. According to the discharge pattern original image 350, the nozzle pitch is NP, and droplets are discharged from nozzles equivalent to a width W of the pixel array region in the X-axis direction. In FIG. 13A, Nl is the nozzle number of the left end of a discharge nozzle group, and Nr is the nozzle number of the right end of the discharge nozzle group.

FIG. 13B exemplifies assignment of discharge nozzles and non-discharge nozzles according to the first discharge pattern image 351 for the first substrate 2A. The alignment error of the first substrate 2A in the X-axis direction, that is, a shift component SXa, is obtained in step S2-8 of FIG. 7. Here, α in FIG. 13B is the number of discharge nozzles shifted in accordance with the alignment error in the X-axis direction. α can be given by the following equation:

α=SXa/NP(round down to the nearest whole number).

For example, when SXa is in the negative direction, discharge nozzles according to the discharge pattern image 351 for the first substrate 2A are the Nl-αth nozzle to the Nr-αth nozzle.

FIG. 13C exemplifies assignment of discharge nozzles and non-discharge nozzles according to the second discharge pattern image 352 for the second substrate 2B. The alignment error of the second substrate 2B in the X-axis direction, that is, a shift component SXb, is obtained in step S2-8 of FIG. 7. Here, β in FIG. 13C is the number of discharge nozzles shifted in accordance with the alignment error in the X-axis direction. β can be given by the following equation:

β=SXb/NP(round down to the nearest whole number).

For example, when SXb is in the positive direction, discharge nozzles according to the discharge pattern image 352 for the second substrate 2B are the Nl+βth nozzle to the Nr+βth nozzle.

As described above, the controller 11 can control the discharge timings of droplets from the discharge head 5 in accordance with the alignment errors of the respective substrates 2A and 2B in the direction of scanning by the scanning mechanism 14. In accordance with the respective alignment errors of the plurality of substrates 2A and 2B in the non-scanning direction orthogonal to the direction of scanning by the scanning mechanism 14, the controller 11 can correct an image (discharge pattern image) for controlling discharge of droplets from the discharge head 5. Further, in accordance with the respective alignment errors of the plurality of substrates 2A and 2B about axes orthogonal to the scanning direction and the non-scanning direction, the controller 11 can correct an image (discharge pattern image) for controlling discharge of droplets from the discharge head 5.

Although each substrate 2 has one pixel array region in the above-described example, at least one of the plurality of substrates 2A and 2B may have a plurality of pixel array regions (in other words, regions where droplets should be placed). In this case, in a period in which droplets are discharged to a substrate having a plurality of pixel array regions, the controller 11 can control the discharge head 5 based on pieces of discharge control information for controlling discharge of droplets to the respective pixel array regions.

In the above-described example, the substrate stage 3 is not rotated about the θ-axis in the scanning period for placing droplets onto the plurality of substrates 2A and 2B. However, to reduce the alignment error, the substrate stage 3 may be rotated about the θ-axis in the scanning period for placing droplets onto the plurality of substrates 2A and 2B. For example, after discharging droplets onto a plurality of target locations of the first substrate 2A, the controller 11 can rotate the substrate stage 3 in accordance with the rotational error of the second substrate 2B before discharging droplets onto a plurality of target locations of the second substrate 2B.

Also, after rotating the substrate stage 3 so as to correct the rotational error of the first substrate 2A, the controller 11 can discharge droplets onto a plurality of target locations of the first substrate 2A. Then, after rotating the substrate stage 3 so as to correct the rotational error of the second substrate 2B, the controller 11 can discharge droplets onto a plurality of target locations of the second substrate 2B.

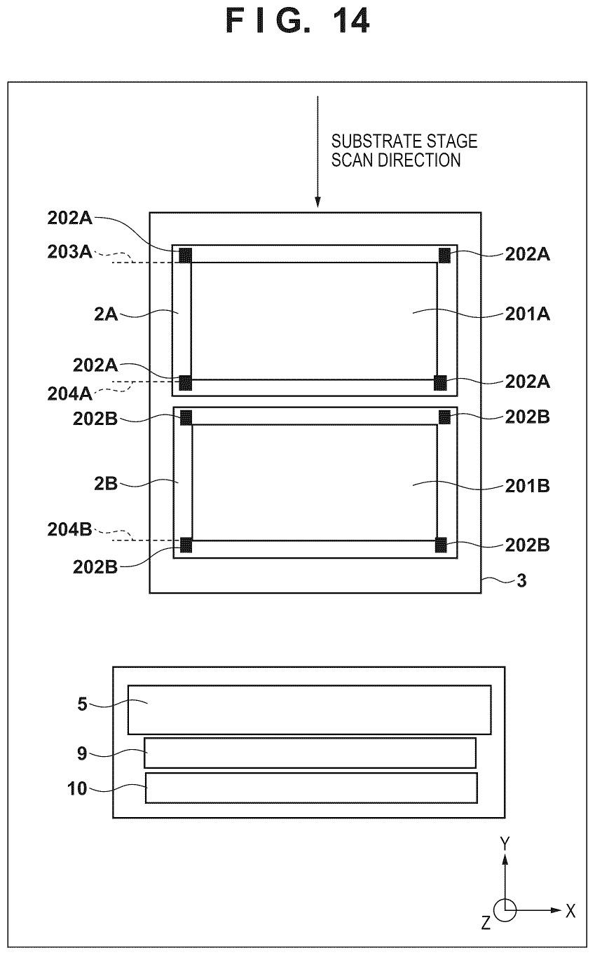

An example in which the substrate stage 3 is scanned in the negative direction along the Y-axis will be explained below. FIG. 14 shows an example in which the scanning direction of the substrate stage 3 is opposite to that in the example of FIG. 3. In the example of FIG. 14, a position 204A on the substrate 2A is a position where placement, application, or discharge of droplets to the pixel array region 201A starts. A position 204B on the substrate 2B is a position where placement, application, or discharge of droplets to the pixel array region 201B starts.

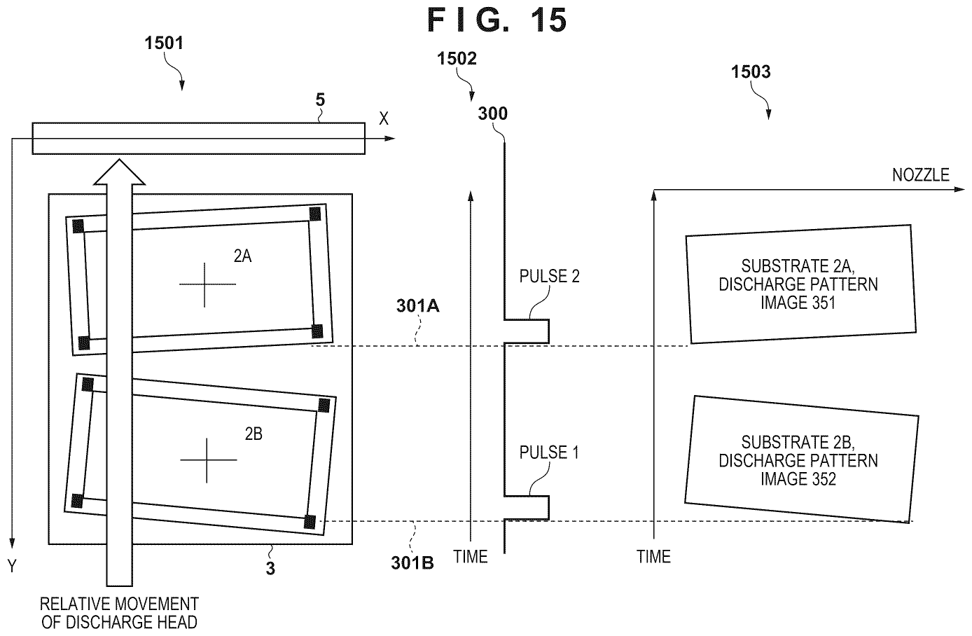

FIG. 15 is a view schematically showing control of the substrate stage 3 by the discharge controller 345 of the controller 11. In FIG. 15, reference numeral 1501 denotes a relative positional relationship between (i) the substrates 2A and 2B mounted on the substrate stage 3 and (ii) the discharge head 5. For convenience, the substrate 2B will be referred to as the first substrate, and the substrate 2A will be referred to as the second substrate. The discharge head 5 relatively moves up in FIG. 15 with respect to the substrate stage 3 to place (print) droplets in the order of the substrate 2B and the substrate 2A. Discharge of droplets to the first substrate 2B starts at the first discharge start position 301B, and discharge of droplets to the second substrate 2A starts at the second discharge start position 301A. The first discharge start position 301B and the second discharge start position 301A are set in step S2-9.

In FIG. 15, reference numeral 1502 denotes the discharge start signal 300. Activation of the discharge start signal 300 is represented by pulse 1 and pulse 2. Pulse 1 and pulse 2 are generated by the comparator 333. Pulse 1 is emitted (generated) at a timing when the substrate stage 3 reaches the first discharge start position 301B, and pulse 2 is emitted (generated) at a timing when the substrate stage 3 reaches the second discharge start position 301A. Note that pulse 1 and pulse 2 are shown as signals output to one signal line in FIG. 15, but may be transmitted to different signal lines. The discharge controller 345 determines the relationship between pulse 1, pulse 2, and the discharge pattern images 351 and 352 in accordance with the scanning direction of the substrate stage 3.

In FIG. 15, reference numeral 1503 schematically denotes the first discharge pattern image 352 for the first substrate 2B and the second discharge pattern image 351 for the second substrate 2A. The first discharge pattern image 352 for the first substrate 2B is the first discharge control information for controlling discharge of droplets from the discharge head 5. The second discharge pattern image 351 for the second substrate 2A is the second discharge control information for controlling discharge of droplets from the discharge head 5. When pulse 1 is emitted, discharge of droplets starts from the discharge head 5 in accordance with the first discharge pattern image 352 for the first substrate 2B. Subsequently, the substrate stage 3 progresses, and when pulse 2 is emitted, discharge of droplets starts from the discharge head 5 in accordance with the second discharge pattern image 351 for the second substrate 2A. The discharge controller 345 outputs the discharge control signal 362 according to the discharge pattern images 352 and 351.

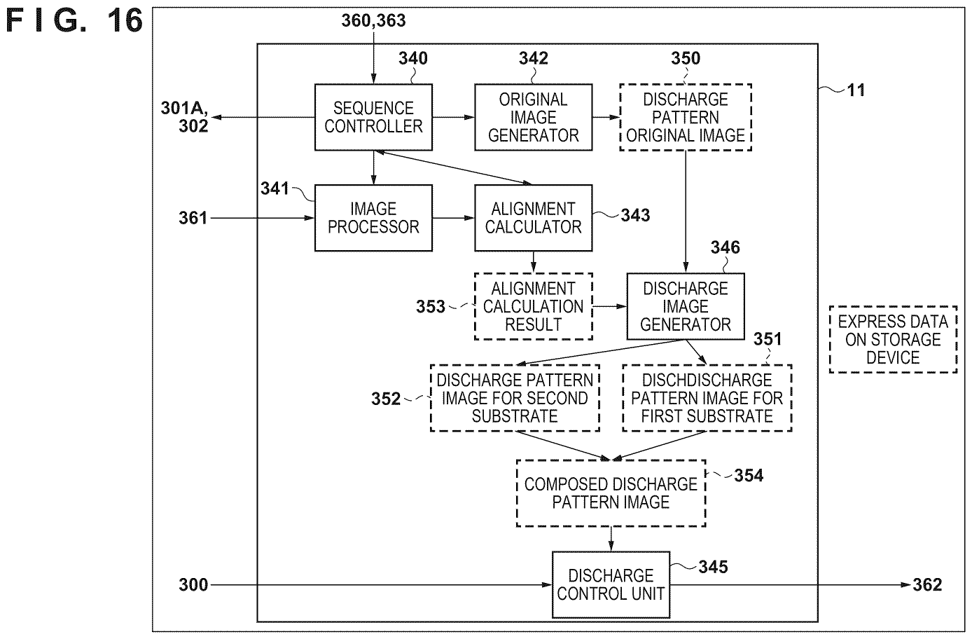

The second embodiment will be explained below. Matters which will not be mentioned in the second embodiment can be pursuant to the first embodiment. FIG. 16 is a functional block diagram of a controller 11 of a droplet placement device 1 according to the second embodiment. A sequence controller 340, an image processor 341, an original image generator 342, an alignment calculator 343, a discharge pattern original image 350, a discharge pattern image for the first substrate, a discharge pattern image 352 for the second substrate, and an alignment calculation result 353 are similar to those in the first embodiment.

A discharge image generator 346 generates a composed discharge pattern image 354 as one image for controlling discharge of droplets to a plurality of target locations of respective substrates 2A and 2B. The discharge image generator 346 generates a first discharge pattern image 351 for controlling discharge of droplets to a plurality of target locations of the first substrate 2A in accordance with the alignment error of the first substrate 2A. In addition, the discharge image generator 346 generates the second discharge pattern image 352 for controlling discharge of droplets to a plurality of target locations of the second substrate 2B in accordance with the alignment error of the second substrate 2B. Further, the discharge image generator 346 generates the composed discharge pattern image 354 by combining the first discharge pattern image 351 and the second discharge pattern image 352. A discharge controller 345 supplies a discharge control signal 362 to a discharge head 5 in accordance with the composed discharge pattern image 354. The discharge controller 345 supplies the discharge control signal 362 to the discharge head 5 so as to place droplets onto all the target locations of the respective substrates 2A and 2B in accordance with one discharge start signal 300.

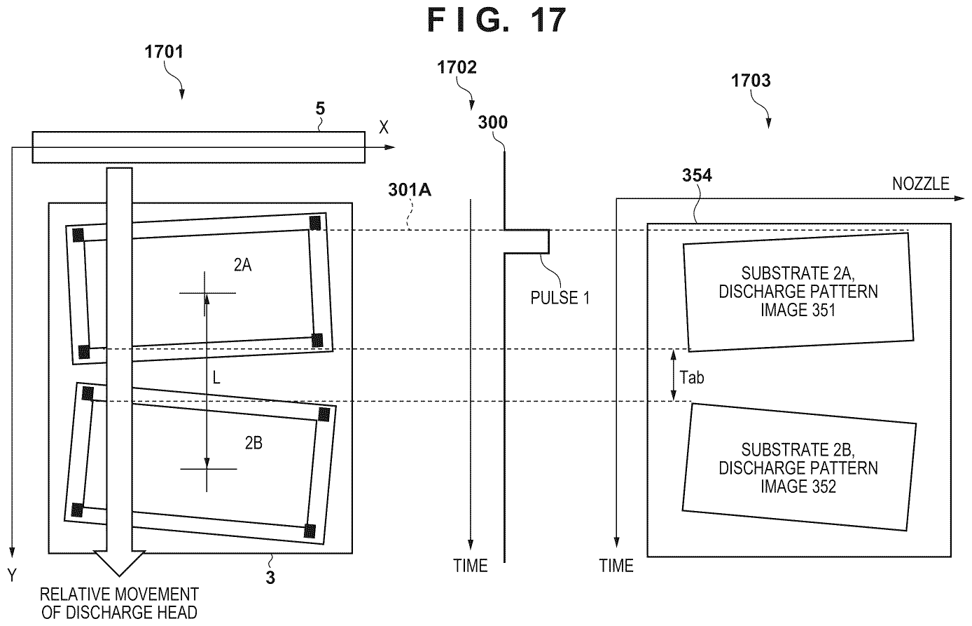

FIG. 17 is a view schematically showing control of a substrate stage 3 by the discharge controller 345 of the controller 11. In FIG. 17, reference numeral 1701 denotes a relative positional relationship between the substrates 2A and 2B mounted on the substrate stage 3, and the discharge head 5. The discharge head 5 relatively moves down in FIG. 17 with respect to the substrate stage 3 to place (print) droplets in the order of the substrate 2A and the substrate 2B.

In FIG. 17, reference numeral 1702 denotes a discharge start signal 300. In the second embodiment, unlike the first embodiment, the discharge start signal 300 provides only pulse 1 as a single start trigger in order to scan a region including the plurality of substrates 2A and 2B. Pulse 1 is emitted at a timing when the pixel array region of the first substrate 2A reaches a start position 301A. In FIG. 17, reference numeral 1703 denotes the composed discharge pattern image 354. In the composed discharge pattern image 354, the discharge pattern image 351 for the first substrate 2A is mapped in accordance with the alignment error of the first substrate 2A so as to reduce the influence of the alignment error. Also, in the composed discharge pattern image 354, the discharge pattern image 352 for the second substrate 2B is mapped in accordance with the alignment error of the second substrate 2B so as to reduce the influence of the alignment error. The composed discharge pattern image 354 represents the pattern of droplets to be discharged from the nozzles of the discharge head 5 at each time. In the composed discharge pattern image 354, a delay Tab equivalent to the interval between the first substrate 2A and the second substrate 2B is set between the first discharge pattern image 351 and the second discharge pattern image 352. The delay Tab can be given by the following equation:

Tab=(L−(Wa+Wb)/2)/V,

where L is the distance between the centers of the substrates 2A and 2B, V is the scanning speed of the substrate stage 3, and Wa and Wb are the sizes of the substrates 2A and 2B in the Y-axis direction. When pulse 1 of the discharge start signal 300 is emitted at the time of driving the substrate stage 3, discharge of droplets starts from the discharge head 5 in accordance with the discharge control signal 362 complying with the composed discharge pattern image 354. Then, printing is performed in accordance with an alignment shift on the substrates 2A and 2B. Droplets are placed onto a plurality of target locations of the respective substrates 2A and 2B so as to reduce the influence of the alignment errors of the substrates 2A and 2B.

A method of manufacturing a display device using the droplet placement device 1 will be explained. The display device manufacturing method can include a droplet placement step of placing droplets onto respective substrates by the droplet placement device 1, and a processing step of processing each substrate having undergone the droplet placement step, thereby obtaining a display device. The processing step can include, for example, a step of forming an upper electrode, a step of forming a wiring pattern, a sealing step, and the like. The manufacturing method can include a circuit formation step of forming a circuit such as a driving circuit on each substrate before the droplet placement step.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2025-014098, which was filed on Jan. 30, 2025 and which is hereby incorporated by reference herein in its entirety.

What is claimed is:

1. A droplet placement device comprising:
a substrate holder configured to hold a plurality of substrates spaced apart from each other;
a discharge head configured to discharge a droplet;
a scanning mechanism configured to relatively move the substrate holder with respect to the discharge head to continuously scan a region including the plurality of substrates with respect to the discharge head;
an alignment measurement device configured to measure alignment errors of the plurality of substrates held by the substrate holder; and
a controller configured to control the discharge head and the scanning mechanism based on the alignment errors measured using the alignment measurement device to provide droplets to a plurality of target locations of the respective substrates in a period in which the region is continuously scanned by the scanning mechanism.

2. The device according to claim 1,
wherein the plurality of substrates include a first substrate and a second substrate,
wherein the period includes a first period in which the first substrate is scanned by the scanning mechanism and includes a second period in which the second substrate is scanned by the scanning mechanism,
wherein the controller generates first discharge control information for controlling discharge of droplets to a plurality of target locations of the first substrate and generates second discharge control information for controlling discharge of droplets to a plurality of target locations of the second substrate, and
wherein the controller controls the discharge head based on the first discharge control information in the first period and controls the discharge head based on the second discharge control information in the second period.

3. The device according to claim 2,
wherein the controller generates a first discharge start signal representing a start of discharge of a droplet to the first substrate and generates a second discharge start signal representing a start of discharge of a droplet to the second substrate, and
wherein the discharge head starts discharge of a droplet to the first substrate based on the first discharge start signal and starts discharge of a droplet to the second substrate based on the second discharge start signal.

4. The device according to claim 1,
wherein the plurality of substrates include a first substrate and a second substrate,
wherein the controller generates one image for controlling discharge of droplets to a plurality of target locations of the first substrate and a plurality of target locations of the second substrate, and
wherein the controller controls the discharge head based on the one image in the period.

5. The device according to claim 4, wherein the controller generates the one image by combining a first discharge pattern image for controlling discharge of droplets to a plurality of target locations of the first substrate in accordance with an alignment error of the first substrate and generates a second discharge pattern image for controlling discharge of droplets to a plurality of target locations of the second substrate in accordance with an alignment error of the second substrate.

6. The device according to claim 5,
wherein the controller generates a discharge start signal representing a start of discharge of a droplet to the first substrate, and
wherein the discharge head controls discharge of droplets to the first substrate and the second substrate based on the discharge start signal and the one image.

7. The device according to claim 1, wherein the controller controls a timing of discharge of a droplet from the discharge head in accordance with an alignment error of each of the plurality of substrates in a direction of scanning by the scanning mechanism.

8. The device according to claim 1, wherein the controller corrects, in accordance with each of alignment errors of the plurality of substrates in a non-scanning direction orthogonal to a direction of scanning by the scanning mechanism, an image for controlling discharge of a droplet from the discharge head.

9. The device according to claim 1, wherein the controller corrects, in accordance with a rotational error of each of the plurality of substrates, an image for controlling discharge of a droplet from the discharge head.

10. The device according to claim 1,
wherein the controller controls a timing of discharge of a droplet from the discharge head in accordance with an alignment error of each of the plurality of substrates in a direction of scanning by the scanning mechanism,
wherein the controller corrects, in accordance with each of alignment errors of the plurality of substrates in a non-scanning direction orthogonal to the direction of scanning by the scanning mechanism, an image for controlling discharge of a droplet from the discharge head, and
wherein the controller corrects, in accordance with each of alignment errors of the plurality of substrates about axes orthogonal to the scanning direction and the non-scanning direction, the image for controlling discharge of a droplet from the discharge head.

11. The device according to claim 1,
wherein the period includes an acceleration period, a constant-speed period following the acceleration period, and a deceleration period following the constant-speed period, and
wherein the controller controls the discharge head and the scanning mechanism to provide droplets to the respective substrates in the constant-speed period.

12. The device according to claim 11, wherein the controller relatively moves the substrate holder along a straight line with respect to the discharge head in the period.

13. The device according to claim 1,
wherein at least one substrate of the plurality of substrates has a plurality of regions, and
wherein the controller controls the discharge head based on pieces of discharge control information for controlling discharge of droplets to the respective regions in a period in which a droplet is discharged to the at least one substrate.

14. The device according to claim 1, wherein the controller controls the discharge head and the scanning mechanism to complete discharge of droplets to the plurality of substrates in a plurality of scans by the scanning mechanism.

15. The device according to claim 1,
wherein the controller generates discharge control information for controlling discharge of droplets to a plurality of target locations of the respective substrates in accordance with a direction in which the substrate holder is relatively moved with respect to the discharge head by the scanning mechanism, and
wherein the controller controls the discharge head based on the discharge control information in the period.

16. The device according to claim 2, wherein after discharging droplets to the plurality of target locations of the first substrate, the controller rotates the substrate holder in accordance with a rotational error of the second substrate before discharging droplets to the plurality of target locations of the second substrate.

17. The device according to claim 2, wherein after rotating the substrate holder to correct a rotational error of the first substrate, the controller performs discharge of droplets to the plurality of target locations of the first substrate, and after rotating the substrate holder to correct a rotational error of the second substrate, performs discharge of droplets to the plurality of target locations of the second substrate.

18. The device according to claim 2, wherein the controller controls the discharge head to adjust a start timing of discharge of a droplet to the first substrate in accordance with an alignment error of the first substrate and to adjust a start timing of discharge of a droplet to the second substrate in accordance with an alignment error of the second substrate.

19. A droplet placement method comprising:
measuring alignment errors of a plurality of substrates held by a substrate holder; and
controlling, based on the alignment errors in the measuring, discharge of droplets from a discharge head to provide the droplets to a plurality of target locations of the respective substrates while continuously scanning a region including the plurality of substrates spaced apart from each other.

20. A display device manufacturing method comprising:
placing droplets onto respective substrates by a droplet placement device; and
processing each substrate having undergone the placing, thereby obtaining a display device,
wherein the droplet placement device comprises:
a substrate holder configured to hold a plurality of substrates spaced apart from each other;
a discharge head configured to discharge a droplet;
a scanning mechanism configured to relatively move the substrate holder with respect to the discharge head to continuously scan a region including the plurality of substrates with respect to the discharge head;
an alignment measurement device configured to measure alignment errors of the plurality of substrates held by the substrate holder; and
a controller configured to control the discharge head and the scanning mechanism based on the alignment errors measured using the alignment measurement device to provide droplets to a plurality of target locations of the respective substrates in a period in which the region is continuously scanned by the scanning mechanism.
